(19) United States
(12) Patent Application Publication
(10) Pub. No.: US 2026/0297465 A1
(43) Pub. Date: Oct. 1, 2026

(54) PROCESSING SOLUTION, METHOD FOR PROCESSING SEMICONDUCTOR SUBSTRATE, AND METHOD FOR MANUFACTURING SEMICONDUCTOR DEVICE

(71) Applicant: TOKYO OHKA KOGYO CO., LTD., Kanagawa (JP)

(72) Inventor: Kazuya TAJIMA, Kanagawa (JP)

(21) Appl. No.: 19/576,011

(22) Filed: Mar. 24, 2026

Related U.S. Application Data
(60) Provisional application No. 63/778,015, filed on Mar. 26, 2025.

(51) Int. Cl. C11D 7/08; C11D 7/10; C11D 7/32; H10P 70/00; H10W 20/00; H10W 20/44

(52) U.S. Cl. CPC C11D 7/08; C11D 7/10; C11D 7/3209; C11D 7/3281; H10P 70/27; H10W 20/4441; C11D 2111/22; H10W 20/067

(57) ABSTRACT

Provided are a processing solution containing: (A) an oxidizing agent; (B) a compound capable of releasing a fluoride ion; (C) at least one selected from the group consisting of a nitrogen atom-containing heterocyclic ring-containing compound and a salt thereof as a first corrosion inhibitor; (D) at least one selected from the group consisting of an amine compound (1) having a specific structure and a salt thereof as a second corrosion inhibitor; and water, in which the content amount of (B) the compound capable of releasing a fluoride ion is 0.005 to 1 mass %, and the content amount of (C) the first corrosion inhibitor is 0.01 to 1 mass %, a method for processing a semiconductor substrate using the processing solution, and a method for manufacturing a semiconductor device using the processing solution.

### CROSS-REFERENCE TO RELATED APPLICATION

The present application claims priority to U.S. Provisional Patent Application No. 63/778,015, filed with the United States Patent and Trademark Office on Mar. 26, 2025, the entirety of which is incorporated by reference in the present specification.

### BACKGROUND OF THE INVENTION

### 1. Technical Field

The present invention relates to a processing solution, a method for processing a semiconductor substrate, and a method for manufacturing a semiconductor device.

### 2. Description of the Related Art

In the course of manufacturing a semiconductor device such as a semiconductor element, a dry etching step is usually employed when forming a semiconductor integrated circuit. In the dry etching step, a titanium-based hard mask (HM) or the like such as titanium nitride (TiN) is used as a protective film for a semiconductor substrate, and it is necessary to remove the titanium-based hard mask or the like. Metal wiring (for example, tungsten, molybdenum, or the like) is used for the semiconductor substrate to be processed.

Examples of such a processing solution may include a processing solution (SPM cleaning or the like) using sulfuric acid and hydrogen peroxide water in combination, a cleaning solution (SC-1 cleaning or the like) using hydrogen peroxide water and ammonia water in combination, and the like. As a technology regarding such a processing solution, for example, Patent Literature 1 describes a processing solution for a semiconductor device, the processing solution containing: a fluorine-containing compound; and a water-soluble aromatic compound that does not have a heterocyclic group and that has a benzene ring, the processing solution having a pH of 5 or less.
Patent Literature 1: International Publication No. WO 2018/061582.

### SUMMARY OF THE INVENTION

However, a conventional cleaning solution like that described above has a problem that, even if it has successfully removed the titanium-based hard mask layer, it damages the metal wiring. In particular, in the case of processing a semiconductor substrate on which a layer containing tungsten atoms (a tungsten atom-containing layer) or a layer containing molybdenum atoms (a molybdenum atom-containing layer) is mounted as metal wiring, there is a problem that, even if a titanium-based hard mask layer and titanium-based residues have successfully been removed to some degree, the tungsten atom-containing layer or the molybdenum atom-containing layer is damaged. Thus, ability to sufficiently remove the titanium-based mask and the titanium-based residues and ability to suppress corrosion on the tungsten atom-containing layer and the molybdenum atom-containing layer are required; however, there is still room for improvement.

Thus, the present invention has been made in view of such circumstances, and an object of the present invention is to provide a processing solution excellent in ability to remove a titanium atom-containing layer and titanium-based residues and excellent in anticorrosion properties for a tungsten atom-containing layer and a molybdenum atom-containing layer, a method for processing a semiconductor substrate using the processing solution, and a method for manufacturing a semiconductor device using the processing solution.

As a result of extensive studies to achieve the object described above, the present inventor has unexpectedly found that it is useful to create a processing solution containing (A) an oxidizing agent, (B) a compound capable of releasing a fluoride ion, (C) at least one selected from the group consisting of a nitrogen atom-containing heterocyclic ring-containing compound and a salt thereof as a first corrosion inhibitor, (D) at least one selected from the group consisting of an amine compound (1) having a specific structure and a salt thereof as a second corrosion inhibitor, and water, and has completed the present invention.

That is, the present invention is as follows.

<1>

A processing solution containing: (A) an oxidizing agent; (B) a compound capable of releasing a fluoride ion; (C) at least one selected from the group consisting of a nitrogen atom-containing heterocyclic ring-containing compound and a salt thereof as a first corrosion inhibitor; (D) at least one selected from the group consisting of an amine compound (1) having a structure represented by Formula (1) and a salt thereof as a second corrosion inhibitor; and water, in which a content amount of (B) the compound capable of releasing a fluoride ion is 0.005 to 1 mass %, and a content amount of (C) the first corrosion inhibitor is 0.01 to 1 mass %,

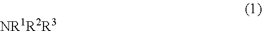

(in which R¹, R², and R³ each independently represent a hydrogen atom, an alkyl group, or an alkyl group having an organic group, provided that at least one of R¹, R², and R³ represents an alkyl group having 8 or more carbon atoms or an alkyl group having 8 or more carbon atoms and having an organic group).
   <2>

The processing solution according to <1>, in which (C) the first corrosion inhibitor is at least one selected from the group consisting of a benzotriazole ring-containing compound, a triazole ring-containing compound, a benzimidazole ring-containing compound, an imidazole ring-containing compound, an indazole ring-containing compound, a pyrazole ring-containing compound, a benzothiazole ring-containing compound, and salts thereof.

<3>

The processing solution according to <1>, in which (C) the first corrosion inhibitor is at least one selected from the group consisting of 5-methyl-1H-benzotriazole, 5-methyl-1H-benzimidazole, 2,6-dimethylbenzothiazole, 1,2,3-benzotriazole, 1H-1,2,3-triazolo[4,5-b]pyridine, indazole, 3-phenylpyrazole, 1,2,4-triazole, 2-propylimidazole, 4-fluoroindazole, 5-nitroindazole, indazole-3-carboxylic acid, 5-methyl-1H-indazole, and salts thereof.

<4>

The processing solution according to <1>, in which (D) the second corrosion inhibitor is at least one selected from the group consisting of n-octylamine, 1-aminodecane, dodecylamine, hexadecylamine, N,N-dimethyldodecylamine, N,N-dimethyltetradecylamine, and N,N-dimethylhexadecylamine.

<5>

The processing solution according to <1>, in which a content amount of (A) the oxidizing agent is 0.0001 to 3 mass %.

<6>

The processing solution according to <1>, in which a content amount of (D) the second corrosion inhibitor is 0.0001 to 10 mass %.

<7>

The processing solution according to <1>, in which a mass ratio (D/C) of a content amount of (D) the second corrosion inhibitor to a content amount of (C) the first corrosion inhibitor is 0.001 to 10.

<8>

The processing solution according to <1>, used for processing of a semiconductor substrate including a substrate, a layer containing tungsten atoms and/or a layer containing molybdenum atoms, and a layer containing titanium atoms.

9>

A method for processing a semiconductor substrate, the method including a step of using the processing solution according to <1> to process a semiconductor substrate including a substrate, a layer containing tungsten atoms and/or a layer containing molybdenum atoms, and a layer containing titanium atoms.

<10>

A method for manufacturing a semiconductor device, the method including a step of using the processing solution according to <1> to process a semiconductor substrate including a substrate, a layer containing tungsten atoms and/or a layer containing molybdenum atoms, and a layer containing titanium atoms.

According to the present invention, a processing solution excellent in ability to remove a titanium atom-containing layer and titanium-based residues and excellent in anticorrosion properties for a tungsten atom-containing layer and a molybdenum atom-containing layer, a method for processing a semiconductor substrate using the processing solution, and a method for manufacturing a semiconductor device using the processing solution can be provided.

### BRIEF DESCRIPTION OF THE DRAWING

FIG. 1 is a cross-sectional view of an example of a semiconductor substrate to be processed with a processing solution according to the present embodiment.

### DETAILED DESCRIPTION

Hereinbelow, a form for implementing the present invention (hereinafter, simply referred to as “the present embodiment”) is described in detail. The following present embodiment is an example for describing the present invention, and is not intended to limit the present invention to the following contents. The present invention can be implemented with modification within the scope of the gist thereof as appropriate. The configurations and parameters disclosed in the present specification can be arbitrarily combined unless otherwise specified. Further, the upper limits and the lower limits of the values disclosed in the present specification can be arbitrarily combined unless otherwise specified.

In the drawing, the same elements are denoted by the same reference numerals, and a repeated description is omitted. The positional relationships such as up, down, left, and right are, unless otherwise specified, based on the positional relationships shown in the drawing. The dimensional ratios in the drawing are not limited to the shown ratios.

In the present specification, the term “comprise” may be changed to “be”, “be made of”, “consist essentially of”, or “consist of” as necessary. With regard to, for example, the identity of components, members, etc., the term “comprise” may be changed to “be” as necessary. The expression “A and/or B” means “A, B, or both of them” unless otherwise specified.

In the present specification, the expression “doing or to do” of “doing/to do something” or the like may refer to “process” or “step”, “process” may refer to “doing or to do” or “step”, and “step” may refer to “doing or to do” or “process”. In the present specification, the term “process” of “process” or the like may refer to “apparatus or unit that is configured to perform the process”, the term “apparatus” may refer to “mechanism or unit”, and the term “unit” may refer to “unit or apparatus provided for a mechanism, an apparatus, a system, or the like”.

### <Processing Solution>

A processing solution according to the present embodiment is a processing solution containing: (A) an oxidizing agent; (B) a compound capable of releasing a fluoride ion; (C) at least one selected from the group consisting of a nitrogen atom-containing heterocyclic ring-containing compound and a salt thereof as a first corrosion inhibitor; (D) at least one selected from the group consisting of an amine compound (1) having a structure represented by Formula (1) and a salt thereof as a second corrosion inhibitor; and water, in which the content amount of (B) the compound capable of releasing a fluoride ion is 0.005 to 1 mass %, and the content amount of (C) the first corrosion inhibitor is 0.01 to 1 mass %,

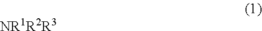

(in which R¹, R², and R³ each independently represent a hydrogen atom, an alkyl group, or an alkyl group having an organic group, provided that at least one of R¹, R², and R³ represents an alkyl group having 8 or more carbon atoms or an alkyl group having 8 or more carbon atoms and having an organic group).

By the processing solution according to the present embodiment, a titanium-based hard mask and titanium-based residues can be removed while suppressing corrosion (damage) on a tungsten atom-containing layer and a molybdenum atom-containing layer. In this respect, a conventional technology has a case where it is particularly difficult to suppress corrosion on a molybdenum atom-containing layer (for example, a molybdenum-based metal layer); however, by the present embodiment, damage even to such a molybdenum atom-containing layer can be suppressed. Furthermore, it is expected to suppress damage to a low-k material and the like. For example, on the above-described substrate on which a tungsten atom-containing layer and/or a molybdenum atom-containing layer is wired, also a low-permittivity film such as a low-k film may be formed. By the processing solution according to the present embodiment, it can be expected to remove the titanium-based hard mask and the titanium-based residues while suppressing damage to such a low-k film.

The reason why the effects described above can be obtained by the processing solution according to the present embodiment is not clear, but is presumed as follows. For example, a film of a titanium-based component (a titanium-based hard mask, titanium-based residues, or the like) can be oxidized by (A) the oxidizing agent, and the oxidized film can be removed by (B) the compound capable of releasing a fluoride ion. By such an action, while the titanium-based hard mask and the titanium-based residues can be removed from on the substrate, damage to the tungsten atom-containing layer and the molybdenum atom-containing layer can be suppressed without reduction in the anticorrosion properties of (C) the first corrosion inhibitor and (D) the second corrosion inhibitor (however, the action and effect of the present embodiment are not limited thereto).

Each component will now be described.

### ((A) Oxidizing Agent)

The processing solution according to the present embodiment contains (A) an oxidizing agent. It is presumed that by the oxidizing agent interacting with titanium atoms of the titanium-based hard mask and the titanium-based residues, the processing solution according to the present embodiment can remove the titanium-based hard mask and the titanium-based residues with good efficiency (however, the action and effect of the present embodiment are not limited thereto). Specific examples of the oxidizing agent may include an oxoacid capable of donating a proton, and the like.

Specific examples of the oxoacid may include halogen oxoacids (hypochlorous acid, chlorous acid, chloric acid, perchloric acid, hypobromous acid, bromous acid, bromic acid, perbromic acid, hypoiodous acid, iodous acid, iodic acid, periodic acid, and the like), silicic acid, nitrous acid, nitric acid, peroxynitric acid, sulfurous acid, sulfuric acid, persulfuric acid, and the like. The processing solution according to the present embodiment may contain a component of a salt of any of these oxoacids (for example, a sodium salt, a potassium salt, a calcium salt, a barium salt, an ammonium salt, a tetraalkylammonium salt, or the like).

As the halogen oxoacids, for example, oxoacids of iodic acid (oxoacids of iodine), such as hypoiodous acid, iodous acid, iodic acid, and periodic acid, are preferable, and iodic acid is more preferable.

From the viewpoint of balance between ability to remove the titanium-based hard mask and the titanium-based residues and anticorrosion properties for the tungsten atom-containing layer and the molybdenum atom-containing layer, at least one selected from the group consisting of halogen oxoacids, nitrous acid, nitric acid, peroxynitric acid, sulfurous acid, sulfuric acid, persulfuric acid, and salts thereof is preferable among the above oxidizing agents. Among these, at least one selected from the group consisting of oxoacids of iodine, peroxynitric acid, persulfuric acid, and salts thereof is more preferable, and at least one selected from the group consisting of iodic acid, persulfuric acid, and salts thereof (for example, ammonium persulfate and the like) is still more preferable.

For the (A) component, one kind may be used singly, or two or more kinds may be used in combination.

The content amount of the (A) component in the processing solution according to the present embodiment is not particularly limited, but is preferably 0.0001 to 3 mass %. The lower limit of the content amount is more preferably 0.0005 mass % or more. The upper limit of the content amount is more preferably 1 mass % or less, still more preferably 0.2 mass % or less, yet still more preferably 0.1 mass % or less, and even still more preferably 0.05 mass % or less. By setting the content amount of the (A) component in such a range, the balance between ability to remove the titanium-based hard mask and the titanium-based residues and anticorrosion properties for the tungsten atom-containing layer and the molybdenum atom-containing layer can be improved even more.

### ((B) Compound Capable of Releasing a Fluoride Ion)

The processing solution according to the present embodiment contains a compound capable of releasing a fluoride ion. The (B) component needs only to be capable of releasing at least a fluoride ion in the processing solution, and a suitable kind can be selected in view of the kinds of other contained components than the (B) component, the configuration and material of the substrate to be processed, etc., as appropriate. Examples of the compound capable of releasing a fluoride ion may include a fluorine-containing compound.

Specific examples of (B) the compound capable of releasing a fluoride ion are not particularly limited, and may include hydrogen fluoride (HF), ammonium fluoride (NH₄F), tetraalkylammonium fluoride, hexafluorosilicic acid (HFSA), hexafluorophosphoric acid (HPF₆), hexafluorotitanic acid (H₂TiF₆), tetrafluoroboric acid (HBF₄), triethanolamine hydrofluoride, and the like. These compounds may be salts. Examples of the kind of the salt may include an ammonium salt, tetraalkylammonium salts (a tetramethylammonium salt, a tetraethylammonium salt, and the like), alkali metal salts (a sodium salt, a potassium salt, and the like), and the like. For example, in the case of hexafluorophosphoric acid, a hexafluorophosphate (for example, a salt containing PF₆⁻, or the like; for example, NH₄PF₆ or the like) is possible. Examples of the tetraalkylammonium fluoride may include tetramethylammonium fluoride (TMAF) and the like.

Among the above, hydrogen fluoride (HF), hexafluorosilicic acid (HFSA), hexafluorophosphoric acid (HPF₆), and tetrafluoroboric acid (HBF₄) are preferable from the viewpoint of balance between ability to remove the titanium-based hard mask and the titanium-based residues and anticorrosion properties for the tungsten atom-containing layer and the molybdenum atom-containing layer. These compounds may be salts as described above. The (B) component is preferably a compound containing no metal ion.

For the (B) component, one kind may be used singly, or two or more kinds may be used in combination.

The content amount of the (B) component in the processing solution according to the present embodiment is 0.005 to 1 mass %. The lower limit of the content amount is preferably 0.01 mass % or more, and more preferably 0.02 mass % or more. The upper limit of the content amount is preferably 0.5 mass % or less, more preferably 0.3 mass % or less, and still more preferably 0.1 mass % or less. By setting the content amount of the (B) component in such a range, the balance between ability to remove the titanium-based hard mask and the titanium-based residues and anticorrosion properties for the tungsten atom-containing layer and the molybdenum atom-containing layer can be improved even more.

### ((C) First Corrosion Inhibitor)

The processing solution according to the present embodiment contains, as (C) the first corrosion inhibitor, at least one selected from the group consisting of a nitrogen atom-containing heterocyclic ring-containing compound and a salt thereof. The kind of the salt is not particularly limited, and may be any kind that the compound can take. Specific examples of the salt are not particularly limited, and may include a sodium salt, a potassium salt, a calcium salt, a barium salt, an ammonium salt, a tetraalkylammonium salt, a chloride salt, a bromide salt, an iodide salt, and the like. Also a hydrate of the above compound is possible.

Specific examples of the nitrogen atom-containing heterocyclic ring-containing compound are not particularly limited, and preferred examples may include at least one selected from the group consisting of a benzotriazole ring-containing compound, a triazole ring-containing compound, a benzimidazole ring-containing compound, an imidazole ring-containing compound, an indazole ring-containing compound, a pyrazole ring-containing compound, a benzothiazole ring-containing compound, and salts thereof. The kind of each of these salts is not particularly limited, and may be any kind that the compound can take. Specific examples of the salt are not particularly limited. Examples of the cation of the salt may include a sodium salt, a potassium salt, a calcium salt, a barium salt, an ammonium salt, a tetraalkylammonium salt, and the like. Examples of the salt may include acid addition salts such as a hydrochloride, a hydrobromide, a sulfate, a phosphate, an acetate, a methanesulfonate, and a p-toluenesulfonate, and the like.

Examples of the benzotriazole ring-containing compound and the salt thereof may include at least one selected from the group consisting of 1,2,3-benzotriazole, 5-methyl-1H-benzotriazole (5m-BTA), 1-hydroxybenzotriazole, 1-hydroxypropylbenzotriazole, 2,3-dicarboxypropylbenzotriazole, 4-hydroxybenzotriazole, 4-carboxy-1H-benzotriazole, 4-carboxy-1H-benzotriazole methyl ester, 4-carboxy-1H-benzotriazole butyl ester, 4-carboxy-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, 3-aminotriazole, salts thereof, and the like.

Examples of the triazole ring-containing compound and the salt thereof may include at least one selected from the group consisting of 1,2,3-triazole, 1,2,4-triazole, 3-amino-1H-1,2,4-triazole, 1-acetyl-1H-1,2,3-triazolo[4,5-b]pyridine, 1H-1,2,3-triazolo[4,5-b]pyridine, 1,2,4-triazolo[4,3-a]pyridin-3 (2H)-one, 3H-1,2,3-triazolo[4,5-b]pyridin-3-ol, salts thereof, and the like.

Examples of the benzimidazole ring-containing compound and the salt thereof may include at least one selected from the group consisting of 5-methyl-1H-benzimidazole, benzimidazole, 5-fluoro-1H-benzimidazole, 5-amino-1H-benzimidazole, 5,6-dimethyl-1H-benzimidazole, salts thereof, and the like.

Examples of the imidazole ring-containing compound and the salt thereof may include at least one selected from the group consisting of 1-decyl-3-methylimidazolium chloride, 2-ethyl-4-methylimidazole, 2-methylimidazole, 2-ethylimidazole, 2-isopropylimidazole, 2-propylimidazole, 2-butylimidazole, 4-methylimidazole, 2,4-dimethylimidazole, 2-undecylimidazole, 2-aminoimidazole, 2,2′-biimidazole, salts thereof, and the like.

Examples of the indazole ring-containing compound and the salt thereof may include at least one selected from the group consisting of indazole, 5-methyl-1H-indazole, 4-fluoroindazole, 5-nitroindazole, indazole-3-carboxylic acid, 1-benzyl-3-[3-(dimethylamino)propoxy]-1H-indazole hydrochloride, (5-methyl-1H-indazole-3-yl)methanamine, salts thereof, and the like.

Examples of the pyrazole ring-containing compound and the salt thereof may include at least one selected from the group consisting of 3,5-dimethylpyrazole, 3-amino-5-methylpyrazole, 4-methylpyrazole, 3-amino-5-hydroxypyrazole, 3-phenylpyrazole, salts thereof, and the like.

Examples of the benzothiazole ring-containing compound and the salt thereof may include at least one selected from the group consisting of 2,6-dimethylbenzothiazole, 2-methylbenzothiazole, 2-hydroxybenzothiazole, 2-aminobenzothiazole, 7-nitrobenzothiazole, 2-benzothiazolecarboxylic acid, benzothiazole-2-aldehyde, 2,2′-dibenzothiazolyl sulfide, 2-mercaptobenzothiazole, salts thereof, and the like.

The first corrosion inhibitor is preferably at least one selected from the group consisting of 5-methyl-1H-benzotriazole (5m-BTA), 5-methyl-1H-benzimidazole, 2,6-dimethylbenzothiazole, 1,2,3-benzotriazole, 1H-1,2,3-triazolo[4,5-b]pyridine, indazole, 3-phenylpyrazole, 1,2,4-triazole, 2-propylimidazole, 4-fluoroindazole, 5-nitroindazole, indazole-3-carboxylic acid, 5-methyl-1H-indazole, and salts thereof.

For the first corrosion inhibitor, one kind may be used singly, or two or more kinds may be used in combination.

The content amount of the (C) component in the processing solution according to the present embodiment is 0.01 to 1 mass %. The lower limit of the content amount is more preferably 0.03 mass % or more. The upper limit of the content amount is more preferably 0.7 mass % or less, still more preferably 0.5 mass % or less, and yet still more preferably 0.3 mass % or less. By setting the content amount of the (C) component in such a range, the balance between ability to remove the titanium-based hard mask and the titanium-based residues and anticorrosion properties for the tungsten atom-containing layer and the molybdenum atom-containing layer can be improved even more. In the case where the hydrate mentioned above is used as the first corrosion inhibitor, it is preferable that the net content amount excluding the hydration water contained in the hydrate be in the range described above.

### ((D) Second Corrosion Inhibitor)

The processing solution according to the present embodiment contains, as (D) the second corrosion inhibitor, at least one selected from the group consisting of an amine compound (1) having a structure represented by Formula (1) and a salt thereof. The salt is not particularly limited, and examples may include acid addition salts such as a hydrochloride, a hydrobromide, a sulfate, a phosphate, an acetate, a methanesulfonate, and a p-toluenesulfonate, and the like. The kind of the cation is not particularly limited either, and examples may include a sodium salt, a potassium salt, a calcium salt, a barium salt, an ammonium salt, a tetraalkylammonium salt, and the like.

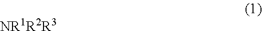

(in which R¹, R², and R³ each independently represent a hydrogen atom, an alkyl group, or an alkyl group having an organic group, provided that at least one of R¹, R², and R³ represents an alkyl group having 8 or more carbon atoms or an alkyl group having 8 or more carbon atoms and having an organic group).

In Formula (1), R¹, R², and R³ each independently need only to be a hydrogen atom, an alkyl group, or an alkyl group having an organic group, provided that at least one of R¹, R², and R³ is an alkyl group having 8 or more carbon atoms or an alkyl group having 8 or more carbon atoms and having an organic group.

The above “alkyl group having 8 or more carbon atoms” is not particularly limited, and may be, for example, a linear alkyl group or a branched alkyl group. The upper limit of the number of carbon atoms of the alkyl group is preferably 20 or less, more preferably 18 or less, and still more preferably 16 or less. Specific examples of the alkyl group having 8 or more carbon atoms may include an octyl group, a nonyl group, a decyl group, an undecyl group, a dodecyl group, a tridecyl group, a tetradecyl group, a pentadecyl group, a hexadecyl group, and the like.

The above “alkyl group having 8 or more carbon atoms and having an organic group” is not particularly limited, and may be, for example, a linear alkyl group or a branched alkyl group. The upper limit of the number of carbon atoms of the alkyl group is preferably 20 or less, more preferably 18 or less, and still more preferably 16 or less. Specific examples of the alkyl group having 8 or more carbon atoms of the above “alkyl group having 8 or more carbon atoms and having an organic group” are not particularly limited; for example, those given as examples of the above “alkyl group having 8 or more carbon atoms” may be employed. Specific examples of the organic group of the above “alkyl group having 8 or more carbon atoms and having an organic group” are not particularly limited, and may include a hydroxy group, a carbonyl group, a carboxy group, a nitro group, an amino group, a sulfo group, an ether group, a halogeno group (for example, a fluoro group, a chloro group, a bromo group, an iodo group, and the like), and the like.

In the case where any of R¹, R², and R³ is an “alkyl group” other than the above “alkyl group having 8 or more carbon atoms” or “alkyl group having 8 or more carbon atoms and having an organic group”, this alkyl group is not particularly limited, and may be, for example, a linear alkyl group or a branched alkyl group. The number of carbon atoms of the alkyl group is not particularly limited, but is preferably, for example, 1 to 7. The lower limit of the number of carbon atoms may be 2 or more, or 3 or more. The upper limit of the number of carbon atoms may be 6 or less, or 5 or less. Specific examples of such an alkyl group may include a methyl group, an ethyl group, a n-propyl group, an iso-propyl group, a n-butyl group, an iso-butyl group, a sec-butyl group, a tert-butyl group, a pentyl group, an iso-pentyl group, a hexyl group, a heptyl group, and the like.

In the case where any of R¹, R², and R³ is an “alkyl group having an organic group” other than the above “alkyl group having 8 or more carbon atoms” or “alkyl group having 8 or more carbon atoms and having an organic group”, this alkyl group is not particularly limited, and may be, for example, a linear alkyl group or a branched alkyl group. The number of carbon atoms of the alkyl group is not particularly limited, but is preferably, for example, 1 to 7. The lower limit of the number of carbon atoms may be 2 or more, or 3 or more. The upper limit of the number of carbon atoms may be 6 or less, or 5 or less. Specific examples of the alkyl group of the above “alkyl group having an organic group” may include a methyl group, an ethyl group, a n-propyl group, an iso-propyl group, a n-butyl group, an iso-butyl group, a sec-butyl group, a tert-butyl group, a pentyl group, an iso-pentyl group, a hexyl group, a heptyl group, and the like. Specific examples of the organic group of the above “alkyl group having an organic group” are not particularly limited, and may include a hydroxy group, a carbonyl group, a carboxy group, a nitro group, an amino group, a sulfo group, an ether group, a halogeno group (for example, a fluoro group, a chloro group, a bromo group, an iodo group, and the like), and the like.

The second corrosion inhibitor is preferably at least one selected from the group consisting of n-octylamine, 1-aminodecane, dodecylamine, hexadecylamine, N,N-dimethyldodecylamine (DMDDA), N,N-dimethyltetradecylamine, and N,N-dimethylhexadecylamine.

For the second corrosion inhibitor, one kind may be used singly, or two or more kinds may be used in combination.

The content amount of the (D) component in the processing solution according to the present embodiment is not particularly limited, but is preferably 0.0001 to 10 mass % with respect to the total mass of the processing solution. The lower limit of the content amount is more preferably 0.0003 mass % or more, still more preferably 0.0005 mass % or more, and yet still more preferably 0.001 mass % or more. The upper limit of the content amount is more preferably 5 mass % or less, still more preferably 3 mass % or less, yet still more preferably 1 mass % or less, and even still more preferably 0.5 mass % or less. By setting the content amount of the (D) component in such a range, the balance between ability to remove the titanium-based hard mask and the titanium-based residues and anticorrosion properties for the tungsten atom-containing layer and the molybdenum atom-containing layer can be improved even more.

In the processing solution according to the present embodiment, the mass ratio (D/C) of the content amount of (D) the second corrosion inhibitor to the content amount of (C) the first corrosion inhibitor is preferably 0.001 to 10. The lower limit of the mass ratio is more preferably 0.003 or more, and still more preferably 0.01 or more. The upper limit of the mass ratio is more preferably 5 or less, still more preferably 3 or less, and yet still more preferably 2 or less. By setting the mass ratio in such a range, the balance between ability to remove the titanium-based hard mask and the titanium-based residues and anticorrosion properties for the tungsten atom-containing layer and the molybdenum atom-containing layer can be improved even more.

The total of the content amount of the first corrosion inhibitor and the content amount of the second corrosion inhibitor in the processing solution according to the present embodiment is not particularly limited, but is preferably 0.0001 to 20 mass % with respect to the total mass of the processing solution. The lower limit of the content amount is more preferably 0.001 mass % or more, and still more preferably 0.03 mass % or more. The upper limit of the content amount is more preferably 10 mass % or less, still more preferably 5 mass % or less, and yet still more preferably 1 mass % or less. By setting the total of the content amount of the first corrosion inhibitor and the content amount of the second corrosion inhibitor in such a range, the balance between ability to remove the titanium-based hard mask and the titanium-based residues and anticorrosion properties for the tungsten atom-containing layer and the molybdenum atom-containing layer can be improved even more.

For the concentration of each component in the processing solution according to the present embodiment, preparation may be performed in advance so as to obtain each content amount described above, or depending on the distribution form or the supply form, a concentrated product may be set ready, and may be diluted for use so as to obtain a desired concentration at the time of use. As a diluting solvent for the concentrated product, water can be used, for example. In this respect, when the processing solution according to the present embodiment is a water-based processing solution described later, there will be also an advantage that such concentration and dilution can be easily performed. During concentration and dilution, purification processing may be appropriately performed as necessary. The technique of purification processing is not particularly limited, and a suitable technique can be employed according to the kind and content amount of the component.

### ((E) Other Components)

The processing solution according to the present embodiment may further contain other optional components than the components described above to the extent that the effects of the present embodiment can be obtained. As such optional components, suitable components can be selected in view of the composition and purpose of use of the processing solution, the material and configuration of the semiconductor substrate to be processed, etc., as appropriate. Examples of such optional components may include a surfactant, a pH adjuster, a buffer, etc.

### (Surfactant)

The processing solution according to the present embodiment may contain a surfactant for the purposes of preventing foaming and adjusting wettability of the processing solution to the substrate, etc. Examples of the surfactant may include a nonionic surfactant, an anionic surfactant, a cationic surfactant, and an amphoteric surfactant.

Examples of the nonionic surfactant may include a polyalkylene oxide alkylphenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzylphenyl ether-based surfactant, an acetylene polyalkylene oxide-based surfactant, and the like.

As these surfactants, generally commercially available ones, such as articles on the market, can be used. For the surfactant, one kind may be used singly, or two or more kinds may be used in combination.

In the case where the processing solution according to the present embodiment contains a surfactant, the content amount of the surfactant is not particularly limited, but is usually, for example, 0.0001 to 5 mass % with respect to the total mass of the processing solution. When the content amount of the surfactant is in such a range, bubbles generated by a foaming agent tend to be minute.

The processing solution according to the present embodiment may be free of one or more selected from the group consisting of a nonionic surfactant, an anionic surfactant, a cationic surfactant, and an amphoteric surfactant, and may be free of one or more of the above compounds given as examples of the surfactants. The processing solution according to the present embodiment may be free of a surfactant.

### (pH Adjuster)

The processing solution according to the present embodiment may contain a pH adjuster. Examples of the pH adjuster may include acidic compounds and basic compounds other than the (A) component, the (B) component, the (C) component, or the (D) component described above. The basic compound may be an organic basic compound or an inorganic basic compound. The processing solution according to the present embodiment may be free of a pH adjuster. Examples of the pH adjuster may include methanesulfonic acid (MSA), phosphoric acid (H₃PO₄, H₄P₂O₇, and HPO₃), carboxylic acids, boric acid (H₃BO₃, or B(OH)₃), phosphorous acid (H₃PO₃), carbonic acid (H₂CO₃), orthocarbonic acid (H₄CO₄, C(OH)₄, or CH₄O₄), sulfuric acid, hydrochloric acid, and the like. Each of the carboxylic acids is an acid having at least one carboxy group (—COOH). Preferred examples of the carboxylic acids may include: monocarboxylic acids such as formic acid, acetic acid, propionic acid, butyric acid, and valeric acid; dicarboxylic acids such as oxalic acid, malonic acid, succinic acid, glutaric acid, and adipic acid; tricarboxylic acids such as citric acid; and the like.

### (Buffer)

The processing solution according to the present embodiment may contain a buffer. The buffer is a compound other than the (A) component, the (B) component, the (C) component, or the (D) component described above, and is a compound having an action of suppressing a change in pH of the processing solution. As the buffer, a compound having pH buffering ability can be used as appropriate.

For the buffer, one kind may be used singly, or two or more kinds may be used in combination. In the case where the processing solution according to the present embodiment contains a buffer, the content amount of the buffer is not particularly limited, but is usually 0.001 to 10 mass % with respect to the total mass of the processing solution. The processing solution according to the present embodiment may be free of a buffer.

### ((F) Water)

The processing solution according to the present embodiment contains water. In the present embodiment, the water is not particularly limited, but is preferably water in which metal ions, organic impurities, particles, etc. are removed or the amounts of them are reduced by distillation, ion exchange processing, filter processing, various kinds of adsorption processing, etc. Preferred examples of the water may include pure water, ultrapure water, deionized water, and the like.

The content amount of water is not particularly limited; the water is used as a solvent. The water as a solvent may be used in combination with an organic solvent described later. The water may be contained as the portion excluding the components described above and the components described below. The content amount of water is usually 40 to 99.999 mass % with respect to the total amount of the processing solution. The lower limit may be, for example, 80 mass % or more, 90 mass % or more, or 95 mass % or more. The upper limit may be, for example, 99.9 mass % or less.

### ((G) Organic Solvent)

The processing solution according to the present embodiment may further contain an organic solvent. In the case of a water-based processing solution containing water as a solvent (described later), a water-soluble organic solvent can be used as the organic solvent. The organic solvent needs only to be an organic solvent miscible with the (A) component, the (B) component, the (C) component, and the (D) component described above, and an appropriate organic solvent can be selected in view of the kinds and content amounts of other components to be used.

Specific examples of the water-soluble organic solvent may include: alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol; ethers such as ethylene glycol monomethyl ether, ethylene glycol monoethyl ether, ethylene glycol monobutyl ether, diethylene glycol monomethyl ether, diethylene glycol monoethyl ether, and diethylene glycol monobutyl ether; acetates such as ethylene glycol monomethyl ether acetate and ethylene glycol monoethyl ether acetate; sulfoxides such as dimethyl sulfoxide (DMSO); sulfones such as dimethylsulfone, diethylsulfone, bis(2-hydroxyethyl) sulfone, and tetramethylenesulfone; amides such as N,N-dimethylformamide (DMF), N-methylformamide, N,N-dimethylacetamide, N-methylacetamide, and N,N-diethylacetamide; lactams such as N-methyl-2-pyrrolidone (NMP), N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; lactones such as γ-butyrolactone and 8-valerolactone; and derivatives thereof. For these, one kind may be used singly, or two or more kinds may be used in combination.

The content amount of the organic solvent with respect to the total of the content amount of water and the content amount of the organic solvent is preferably 40 mass % or less, more preferably 30 mass % or less, still more preferably 20 mass % or less, and yet still more preferably 10 mass % or less. The lower limit of the content amount of the organic solvent with respect to the total of the content amount of water and the content amount of the organic solvent is not particularly limited, and may be 0.01 mass % or more, or 0.1 mass % or more. Examples of combination of the upper limit and the lower limit of the content amount of the organic solvent with respect to the total of the content amount of water and the content amount of the organic solvent may, although it goes without saying that the upper limit values and the lower limit values described above can be arbitrarily combined, include 0.01 mass % or more and 40 mass % or less.

The processing solution according to the present embodiment is preferably a water-based processing solution (occasionally called an aqueous processing solution or the like) from the viewpoint of solubility of components, environmental load reduction, economic efficiency, etc. The water-based processing solution is a processing solution free of organic solvents, or a processing solution that contains water and an organic solvent and in which the content amount of the organic solvent is lower than the content amount of water. From such a point of view, as a more preferred aspect, the content amount of the organic solvent in the processing solution according to the present embodiment is preferably 20 mass % or less, more preferably 10 mass % or less, still more preferably 5 mass % or less, yet still more preferably 3 mass % or less, and even still more preferably 0 mass % (that is, only water being contained as the solvent).

### (Impurities, Etc.)

The processing solution according to the present embodiment may contain, for example, metal impurities including metal atoms such as Fe atoms, Cr atoms, Ni atoms, Zn atoms, Ca atoms, or Pb atoms. The total content amount of atoms of the above metals in the processing solution according to the present embodiment is preferably 100 mass ppt or less with respect to the total mass of the processing solution. The lower limit value of the total content amount of atoms of the metals is preferably as low as possible, and examples may include 0.001 mass ppt or more. Examples of the total content amount of atoms of the metals may include 0.001 mass ppt to 100 mass ppt. By setting the total content amount of atoms of the metals to be equal to or less than the preferred upper limit described above, defect suppression ability and residue suppression ability of the processing solution are improved. It is presumed that by setting the total content amount of atoms of the metals to be equal to or more than the preferred lower limit value described above, the metal atoms are less likely to exist in a separate manner in the system and are less likely to give bad influence to the manufacturing yield of the entire object to be cleaned.

The content amount of metal impurities can be adjusted by, for example, purification processing such as filtering. The purification processing such as filtering may be performed on part or all of the source material before preparing the processing solution, or may be performed after preparation of the processing solution.

The processing solution according to the present embodiment may contain, for example, impurities derived from organic substances (organic impurities). The total content amount of such organic impurities in the processing solution according to the present embodiment is preferably 5000 mass ppm or less. The lower limit of the content amount of organic impurities is preferably as low as possible, and examples may include 1 mass ppq or more. Examples of the total content amount of organic impurities may include 1 mass ppq to 5000 mass ppm.

The processing solution according to the present embodiment may contain, for example, objects to be counted having sizes countable by a light scattering in-liquid particle counter. The size of the object to be counted is, for example, 0.04 μm or more. The number of objects to be counted in the processing solution according to the present embodiment is, for example, 1000 or less per 1 mL of the processing solution, and the lower limit is, for example, 0.1 or more. It is presumed that by the number of objects to be counted in the processing solution being in the range described above, the metal corrosion suppression effect, the defect suppression effect, etc. by the processing solution are improved (however, the action and effect of the present embodiment are not limited thereto).

The size of the object to be counted may be a size detectable by a light scattering in-liquid particle counter, and may be, for example, 0.001 μm or more.

The organic impurities and/or the objects to be counted described above may be added to the processing solution, or may be unavoidably mixed into the processing solution in the manufacturing process of the processing solution. Examples of the case of unavoidable mixing-in in the manufacturing process of the processing solution may include a case where organic impurities are contained in the source material (for example, the organic solvent) used for the manufacturing of the processing solution, a case where organic impurities are mixed in from the external environment in the manufacturing process of the processing solution (for example, contamination), and the like, but the case is not limited thereto.

In the case where objects to be counted are added to the processing solution, the existence ratio may be adjusted for each specific size in view of the surface roughness of the object to be cleaned, etc.

(pH)

The pH of the processing solution according to the present embodiment is not particularly limited, but is preferably 0 to 4. The lower limit of pH is more preferably 1 or more. The upper limit of pH is more preferably 4 or less, still more preferably 3 or less, yet still more preferably 2 or less, and even still more preferably 1 or less. By pH being in such a range, both anticorrosion properties and cleaning performance can be easily achieved.

As described above, the processing solution according to the present embodiment is excellent in ability to remove a titanium atom-containing layer and titanium-based residues, and is excellent also in anticorrosion properties for a tungsten atom-containing layer and a molybdenum atom-containing layer. Thus, the processing solution according to the present embodiment can be suitably used for processing of a semiconductor substrate including a substrate, a layer containing tungsten atoms and/or a layer containing molybdenum atoms, and a layer containing titanium atoms. Details regarding the processing of a semiconductor substrate will be described later when describing a method for processing a semiconductor substrate and a method for manufacturing a semiconductor device.

### <Method for Processing a Semiconductor Substrate>

Preferred examples of the processing method using the processing solution according to the present embodiment may include a method for processing a semiconductor substrate including a step (processing step) of using the processing solution described above to process a semiconductor substrate including a substrate, a layer containing tungsten atoms and/or a layer containing molybdenum atoms, and a layer containing titanium atoms. Examples of the semiconductor substrate to be processed are given below.

Examples of the configuration of a stacked substrate of a semiconductor device may include a stacked substrate in which functional layers such as a metal wiring layer, an etching stop layer, an insulating layer, and an interlayer insulating film (ILD), and a protective film (a hard mask layer, an HM layer) are stacked on a substrate.

Examples of the material of the substrate may include substrate materials such as silicon, amorphous silicon, polysilicon, and glass.

Examples of the metal used for the metal wiring or the metal layer may include a material containing at least one selected from the group consisting of metals such as tungsten (W), molybdenum (Mo), cobalt (Co), ruthenium (Ru), gold (Au), silver (Ag), copper (Cu), iron (Fe), nickel (Ni), aluminum (Al), lead (Pb), zinc (Zn), tin (Sn), tantalum (Ta), magnesium (Mg), bismuth (Bi), cadmium (Cd), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), and thallium (Tl), metal oxides, metal nitrides, metal chlorides, and metal fluorides of them, and the like. Examples of inorganic substances other than metal may include silicon (Si), oxides (SiOₓ, x represents the number unless otherwise specified), nitrides (SiN), chlorides (SiClₓ), and fluorides (SiF) of silicon, and the like. From the viewpoint of effectively utilizing the advantages of the present embodiment, tungsten and/or molybdenum is preferably contained. These may be tungsten alloys or molybdenum alloys. In the case of, for example, silicon-based materials, examples may include SiN, SiO₂, a low-k film (a SiOC film, a SiCOH film, or the like), an ILD, and the like.

Examples of the material of the etching stop layer may include aluminum oxide, SiN, SiON, SiOCN, and the like.

Examples of the material of the interlayer insulating film (ILD) may include silicon-based materials such as SiO₂, SiN, SiOC, and SiOCN. The interlayer insulating film can be used as, for example, a functional layer that insulates wiring layers of multilayer wiring composed of a plurality of layers.

The material of the protective film (a hard mask layer, an HM layer) needs only to be a material functioning as a protective film against etching, and is not particularly limited, and a suitable material can be selected in view of manufacturing conditions, etc., as appropriate. Examples of the material of the protective film may include titanium-based materials such as Ti and TiN, silicon-based materials such as SiN, SiO₂, SiON, and SiCN, combinations of them, and the like. In this respect, the protective film is preferably a layer containing titanium atoms from the viewpoint that the processing solution according to the present embodiment is excellent in ability to remove a titanium-based mask and titanium-based residues. Examples of the material used for the layer containing titanium atoms may include a titanium-based material. Preferred examples of the titanium-based material may include titanium (Ti), titanium nitride (TiN), titanium oxide (TiOₓ (x represents the number)), titanium oxynitride (TiON), titanium oxyfluoride (TiOF), and the like.

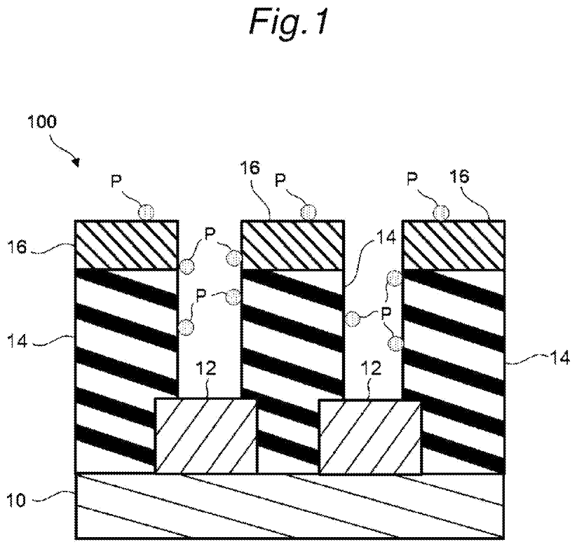

FIG. 1 is a cross-sectional view of an example of a semiconductor substrate to be processed with the processing solution according to the present embodiment.

In a semiconductor substrate 100 shown in FIG. 1, a metal wiring layer 12, a low-k film 14, and a hard mask layer (HM layer) 16 are formed on a substrate 10 (the substrate 10/the metal wiring layer 12/the low-k film 14/the hard mask layer 16).

As the material of the substrate 10, the material described above can be used.

As the metal wiring layer 12, the material described above can be used, but a tungsten atom-containing layer and/or a molybdenum atom-containing layer is preferable from the viewpoint that the effects of the present embodiment can be exhibited. These include a layer containing tungsten atoms and molybdenum atoms. As the metal wiring layer, a tungsten atom-containing layer and a molybdenum atom-containing layer may be used in combination, or a tungsten atom-containing layer, a molybdenum atom-containing layer, and other metal-containing layers may be used in combination. In this respect, in the manufacturing process of a semiconductor device, reductions in size and weight of the constituent components have been advanced, and handling of these components may be difficult in the manufacturing process; therefore, the willingness to use tungsten or molybdenum may have been forced to be negative. However, the processing solution according to the present embodiment is excellent in anticorrosion properties for a tungsten atom-containing layer and a molybdenum atom-containing layer, and therefore can solve also the problem of such structural restriction.

As the low-k film 14, the material described above can be used.

As the hard mask layer 16, the material described above can be used, but titanium-based materials such as titanium and titanium-based alloys are preferable from the viewpoint that the effects of the present embodiment can be exhibited.

As an aspect of the processing method according to the present embodiment, at least removal of etching residues is preferably performed as processing. Examples may include performing a processing step using the processing solution according to the present embodiment after performing dry etching.

The processing solution according to the present embodiment is suitable for removal of etching residues, and is suitable particularly for removal of dry etching residues. Dry etching residues are usually removed before the next step from the viewpoint of improving the yield of the semiconductor and preventing deterioration of electrical characteristics. Thus, the processing solution according to the present embodiment is, for example, suitably used after dry etching is performed in a wiring process. That is, the processing solution according to the present embodiment can be suitably used for cleaning of a semiconductor substrate after dry etching.

For example, the processing solution according to the present embodiment can successfully remove residues P such as residues of a titanium-based material (titanium-based residues, residues containing titanium and/or a titanium-based alloy) that are derived from the hard mask layer 16 and that adhere in the wiring process, and etching residues containing inorganic substances derived from the metal wiring layer. In particular, titanium-based residues attached to the semiconductor substrate after dry etching are residues that have high wet resistance and are difficult to remove by cleaning processing, but the processing solution according to the present embodiment can clean such residues off with good efficiency.

The processing solution according to the present embodiment can be suitably used for processing of a semiconductor substrate. Preferred examples of the method for processing a semiconductor substrate may include a method for processing a semiconductor substrate including a step of using the processing solution described above to process a semiconductor substrate including a substrate, a layer containing tungsten atoms and/or a layer containing molybdenum atoms, and a layer containing titanium atoms. A processing method will now be described by using, as an example, a case of processing the semiconductor substrate 100 shown in FIG. 1 described above.

The processing method according to the present embodiment is a step of using the processing solution described above to process the semiconductor substrate 100 after dry etching is performed by a wiring process. The method of processing is not particularly limited, and a known processing method can be used. An operation may be performed in which, when bringing the processing solution into contact with the semiconductor substrate 100 to be processed, the processing solution is diluted 2 to 2000 times to obtain a diluted solution having a desired concentration described above, and then the diluted solution is used to perform cleaning.

The processing step using the processing solution according to the present embodiment may be a step of bringing the processing solution described above into contact with the semiconductor substrate 100. For example, the processing solution may be brought into contact with the semiconductor substrate 100 in an etching step (or a step before or after the etching step), and thereby etching residues can be removed. Also removal of a protective film such as the hard mask layer 16 can be expected. The etching method is not particularly limited, and may be wet etching or dry etching, but is preferably dry etching. The case of dry etching is advantageous from the viewpoint that nano-level metal wiring is possible and also control of the gas used is possible. Further, in the case of dry etching, although there is a concern that damage to the substrate, etc. may be relatively large, such damage can be effectively suppressed by using the processing solution according to the present embodiment; thus, the case of dry etching is desirable also in that from such a point of view the advantage of the present embodiment can be reflected more effectively.

As a method for making contact with the semiconductor substrate 100, for example, the processing solution is put into a container, and the semiconductor substrate 100 to be cleaned is immersed in the processing solution; thereby, residues P such as dry etching residues can be removed. Also an operation in which a sheet-fed cleaning system is used to process electronic devices and thereby dry etching residues are removed is possible. The processing solution is suitably used not only as a dry etching residue removal solution (cleaning solution) but also as an etching solution. The processing solution according to the present embodiment can be used also as a cleaning solution for cleaning an electronic device after a step of chemical mechanical polishing (CMP). Examples of the operation in the processing step may include a method of continuously applying the processing solution onto the semiconductor substrate 100 rotating at a constant speed (a spin coating method), a method of immersing the semiconductor substrate 100 in the processing solution for a certain period of time (a dipping method), a method of spraying the processing solution on the surface of the semiconductor substrate 100 (a spraying method), and the like.

The processing temperature is not particularly limited, but a condition of 10 to 80° C. is preferable. The lower limit of the processing temperature is more preferably 20° C. or higher, and still more preferably 30° C. or higher. The upper limit of the processing temperature is more preferably 70° C. or lower, and still more preferably 60° C. or lower. By setting the lower limit of the processing temperature in the range described above, the ability to remove residues P can be improved even more. By setting the upper limit of the processing temperature in the range described above, an unintended compositional change of the processing solution can be suppressed even more effectively, and cleaning can be performed with even better efficiency from the viewpoint of workability, safety, cost, etc.

As the processing time, an enough period of time to remove etching residues, impurities, etc. attached to the surface of the semiconductor substrate 100 can be selected as appropriate. Preferred examples of the processing time may include 10 seconds to 30 minutes. The lower limit of the processing time is more preferably 20 seconds or more, and still more preferably 30 seconds or more. The upper limit of the cleaning time is more preferably 15 minutes or less, still more preferably 10 minutes or less, and yet still more preferably 5 minutes or less.

Before and after the processing step, a rinsing step using an organic solvent, water, carbonated water, ammonia water, or the like, etc. may be performed.

Thus, by using the processing solution according to the present embodiment, in the semiconductor substrate 100 to which residues P are attached, the hard mask layer 16 (for example, a titanium-based mask containing titanium and/or a titanium alloy, or the like) and residues P (for example, titanium-based residues or the like) can be effectively removed while suppressing damage to the metal wiring layer 12 (for example, a tungsten atom-containing layer, a molybdenum atom-containing layer, or the like).

### <Method for Manufacturing a Semiconductor Device, Etc.>

The processing solution according to the present embodiment and the processing method using the same can be suitably used as a method for manufacturing a semiconductor device. Examples of the method for manufacturing a semiconductor device according to the present embodiment may include a method for manufacturing a semiconductor device including a step of using the processing solution described above to process a semiconductor substrate including a substrate, a layer containing tungsten atoms and/or a layer containing molybdenum atoms, and a layer containing titanium atoms.

Examples of such a method for manufacturing a semiconductor device may include a method for manufacturing a semiconductor device including (1) a step of preparing a semiconductor substrate having a protective film, and (2) a step of performing etching of the protective film and/or removal of impurities on the semiconductor substrate, and the like. The (2) step can be performed as processing using the processing solution. In the case of, for example, the semiconductor substrate 100 shown in FIG. 1, the hard mask layer 16 corresponds to the protective film herein. Hereinafter, the case of the semiconductor substrate 100 shown in FIG. 1 is described as an example.

### (1) Step of Preparing a Substrate Having a Protective Film

In step (1), a substrate having at least a protective film is prepared. In the case of FIG. 1, a semiconductor substrate 100 before etching including a substrate 10, a metal wiring layer 12, a low-k film 14, and a hard mask layer (HM layer) 16 in this order is prepared. The method for stacking the metal wiring layer 12, the low-k film 14, and the hard mask layer (HM layer) 16 on the substrate 10 is not particularly limited, and a known method can be employed.

(2) Step of Performing Etching of the Protective Film and/or Removal of Impurities on the Semiconductor Substrate

Subsequently, etching of the protective film and/or removal of impurities on the semiconductor substrate is performed. In the case of FIG. 1, etching of the hard mask layer (HM layer) 16 and/or removal of impurities P on the semiconductor substrate 100 is performed. In the (2) step, etching and removal of impurities P may be performed simultaneously or sequentially. Alternatively, either one may be performed.

The method of etching is not particularly limited, and may be wet etching or dry etching, but is preferably dry etching. The case of dry etching is advantageous from the viewpoint that nano-level metal wiring is possible and also control of the gas used is possible. Further, in the case of dry etching, although there is a concern that damage to the substrate, etc. may be relatively large, such damage can be effectively suppressed by using the processing solution according to the present embodiment. Thus, the case of dry etching is desirable also in that such an advantage of the present embodiment can be reflected more effectively.

In the case of dry etching, for example, plasma can be used. Usually, in the case of performing plasma etching, there may be a problem that the substrate is likely to be damaged and a problem that plasma etching residues are generated and thus it is necessary to clean them off with a processing solution; however, when the processing solution according to the present embodiment is used, such problems can be effectively suppressed.

As a method for removing impurities P on the semiconductor substrate 100, a method in which the processing solution described above is brought into contact with the semiconductor substrate 100 and thereby the impurities are removed from on the semiconductor substrate 100 can be employed. As this method, for example, the processing method (cleaning method) described above can be used. Thus, a semiconductor device can be obtained by removing the hard mask layer 16 from the semiconductor substrate 100 and removing the residues P. After cleaning, known post-processing may be performed as necessary.

As described hereinabove, the processing solution according to the present embodiment can be used for, for example, removal of a protective film of a semiconductor substrate, and removal or cleaning off of residues generated in an etching step or the like. In particular, the processing solution according to the present embodiment has advantages of being excellent in ability to remove a titanium-based mask and titanium-based residues and being excellent in anticorrosion properties for both a tungsten atom-containing layer and a molybdenum atom-containing layer.

The processing solution according to the present embodiment can obtain a sufficient effect even when it is free of hydrogen peroxide. The processing solution according to the present embodiment can obtain a sufficient effect even when it is free of hydroxylamine. The processing solution according to the present embodiment can obtain a sufficient effect even when it is free of tetramethylammonium hydroxide (TMAH) and/or tetraethylammonium hydroxide (TEAH). From such a point of view, the processing solution according to the present embodiment may be a processing solution free of hydrogen peroxide. The processing solution according to the present embodiment may be a processing solution free of hydroxylamine. The processing solution according to the present embodiment may be a processing solution free of tetramethylammonium hydroxide (TMAH). The processing solution according to the present embodiment may be a processing solution free of tetraethylammonium hydroxide (TEAH).

### Examples

The present invention will now be described in more detail by using the following Examples and Comparative Examples, but the present invention is not limited by the following Examples at all.

### <Preparation of a Processing Solution>

The components were mixed to obtain the respective compositions shown in the tables, and processing solutions of the Examples and the Comparative Examples were prepared. Water was prepared as the balance of each processing solution. For example, Example 1 is a processing solution containing 0.0025 mass % of HIO₃, 0.025 mass % of HFSA, 0.3 mass % of 5mBTA, 0.015 mass % of dodecylamine, 1 mass % of MSA, and water as the balance, and having a pH of less than 1. The abbreviations, etc. written in the tables are as follows. In the following description and tables, for the sake of convenience, also the components of the Comparative Examples are written by being included in the items of “(A) component”, “(B) component”, “(C) component”, “(D) component”, and “pH Adjuster”.

(A) component
HIO₃: iodic acid
Ammonium persulfate

### (B) Component

HFSA: hexafluorosilicic acid
HF: hydrogen fluoride

### (C) Component

5mBTA (5-Methyl-1H-benzotriazole)
5-Methyl-1H-benzimidazole
2,6-Dimethylbenzothiazole
1,2,3-Benzotriazole
1H-1,2,3-Triazolo[4,5-b]pyridine
Indazole
3-Phenylpyrazole
4-Fluoroindazole
5-Nitroindazole
Indazole-3-carboxylic Acid
5-Methyl-1H-indazole

### (D) Component

1-Dodecanol
4-(Dodecyloxy)benzoic Acid
Dodecylamine
1-Aminodecane
N,N-Dimethyldodecylamine (DMDDA)
n-Octylamine
Hexadecylamine
N,N-Dimethyltetradecylamine
N,N-Dimethylhexadecylamine

### pH Adjuster

MSA: methanesulfonic acid
Benzenesulfonic acid
HCl: hydrochloric acid
HBr: hydrobromic acid

### <Evaluation of Ability to Remove TiN Residues>

TiN was deposited by the CVD method, and thereby a TiN substrate in which a TiN film (film thickness: 50 nm) was formed on a substrate (material: SiO₂, film thickness: 100 nm) was prepared. Then, cutting was performed into 2 cm×2 cm, and a sample substrate was obtained. Subsequently, 100 mL of the processing solution of each of the Examples and the Comparative Examples was put into a beaker, the sample substrate was immersed in the processing solution under the conditions of 40° C. and 3 minutes, then rinsing was performed with ultrapure water (25° C.) for 3 seconds, then cleaning was performed with isopropyl alcohol (25° C.) for 30 seconds, and drying was performed by nitrogen blowing. Then, TiN etching ability was evaluated based on the film thickness difference of the TiN film between before and after immersion in the processing solution. The film thicknesses before and after processing were measured by the X-ray fluorescence analysis method using “ZSX Primus IV” (manufactured by Rigaku Corporation). For example, the ER of the TIN HM (hard mask) of Example 1 was 47 Å/min, and this means that etching was performed 141 Å in 3 minutes.

### <Evaluation of Mo Anticorrosion Properties>

Molybdenum was deposited by the CVD method, and thereby a molybdenum film substrate in which a molybdenum film (film thickness: 50 nm) was formed on a substrate (material: SiO₂, film thickness: 100 nm) was prepared. Then, cutting was performed into 2 cm×2 cm, and a sample substrate was obtained. Subsequently, 100 mL of the processing solution of each of the Examples and the Comparative Examples was put into a beaker, the sample substrate was immersed in the processing solution under the conditions of 40° C. and 3 minutes, then rinsing was performed with ultrapure water (25° C.) for 3 seconds, then cleaning was performed with isopropyl alcohol (25° C.) for 30 seconds, and drying was performed by nitrogen blowing. Then, anticorrosion properties were evaluated based on the film thickness difference of the molybdenum film between before and after immersion in the processing solution. The film thicknesses before and after processing were measured by the X-ray fluorescence analysis method using “ZSX Primus IV” (manufactured by Rigaku Corporation). For example, the ER of Mo of Example 1 was 7 Å/min, and this means that etching was performed at a depth of 21 Å in 3 minutes.

### <Evaluation of W Anticorrosion Properties>

Tungsten was deposited by the CVD method, and thereby a tungsten film substrate in which a tungsten film (film thickness: 100 nm) was formed on a substrate (material: SiO₂, film thickness: 100 nm) was prepared. Then, cutting was performed into 2 cm×2 cm, and a sample substrate was obtained. Subsequently, 100 mL of the processing solution of each of the Examples and the Comparative Examples was put into a beaker, the sample substrate was immersed in the processing solution under the conditions of 40° C. and 3 minutes, then rinsing was performed with ultrapure water (25° C.) for 3 seconds, then cleaning was performed with isopropyl alcohol (25° C.) for 30 seconds, and drying was performed by nitrogen blowing. Then, anticorrosion properties were evaluated based on the film thickness difference of the tungsten film between before and after immersion in the processing solution. The film thicknesses before and after processing were measured by the X-ray fluorescence analysis method using “ZSX Primus IV” (manufactured by Rigaku Corporation). For example, the ER of W of Example 1 was 1 Å/min, and this means that etching was performed 3 Å in 3 minutes.

The compositions, characteristics, and evaluation results of the Examples and the Comparative Examples are shown in Tables 1 to 7.

TABLE 1

| | (A) Oxidizing | (B) Fluoride ion | (C) First corrosion | |
|---|---|---|---|---|
| | agent | source compound | inhibitor | (D) Second corrosion |
| | [mass %] | [mass %] | [mass %] | inhibitor [mass %] |
| Comparative | HIO₃ | HFSA | 5mBTA | None |
| Example 1 | 0.0025 | 0.025 | 0.3 | |
| Comparative | HIO₃ | HFSA | 5mBTA | 1-Dodecanol |
| Example 2 | 0.0025 | 0.025 | 0.3 | 0.015 |
| Comparative | HIO₃ | HFSA | 5mBTA | 4-(Dodecyloxy) benzoic Acid |
| Example 3 | 0.0025 | 0.025 | 0.3 | 0.015 |
| Example 1 | HIO₃ | HFSA | 5mBTA | Dodecylamine |
| | 0.0025 | 0.025 | 0.3 | 0.015 |
| Example 2 | HIO₃ | HFSA | 5mBTA | 1-Aminodecane |
| | 0.0025 | 0.025 | 0.3 | 0.015 |
| Example 3 | HIO₃ | HFSA | 5mBTA | N,N-Dimethyldodecylamine |
| | 0.0025 | 0.025 | 0.3 | (DMDDA) |
| | | | | 0.015 |
| Example 4 | HIO₃ | HFSA | 5mBTA | N,N-Dimethylhexadecylamine |
| | 0.0025 | 0.025 | 0.3 | 0.015 |
| Example 5 | HIO₃ | HFSA | 5mBTA | n-Octylamine |
| | 0.0025 | 0.025 | 0.3 | 0.5 |
| Example 6 | HIO₃ | HFSA | 5mBTA | 1-Aminodecane |
| | 0.0025 | 0.025 | 0.3 | 0.15 |
| Example 7 | HIO₃ | HFSA | 5mBTA | Hexadecylamine |
| | 0.0025 | 0.025 | 0.3 | 0.0003 |
| Example 8 | HIO₃ | HFSA | 5mBTA | Hexadecylamine |
| | 0.0025 | 0.025 | 0.3 | 0.015 |

| | (D) Second | | | | | | |
|---|---|---|---|---|---|---|---|
| | corrosion | | | | | | |
| | inhibitor/(C) First | | | | | | |
| | corrosion inhibitor | pH Adjuster | | | TiN | Mo | W |
| | (mass ratio) | [mass %] | Water | pH | [Å/min] | [Å/min] | [Å/min] |
| Comparative | — | MSA | Balance | <1 | 48.9 | 48.5 | 50 |
| Example 1 | | 1 | | | | | |
| Comparative | 0.05 | MSA | Balance | <1 | 50 | 40 | 39 |
| Example 2 | | 1 | | | | | |
| Comparative | 0.05 | MSA | Balance | <1 | 44 | 32 | 29 |
| Example 3 | | 1 | | | | | |
| Example 1 | 0.05 | MSA | Balance | <1 | 47 | 7 | 1 |
| | | 1 | | | | | |
| Example 2 | 0.05 | MSA | Balance | <1 | 56 | 11 | 5 |
| | | 1 | | | | | |
| Example 3 | 0.05 | MSA | Balance | <1 | 52 | 11 | 1 |
| | | 1 | | | | | |
| Example 4 | 0.05 | MSA | Balance | <1 | 45 | 9 | 1 |
| | | 1 | | | | | |
| Example 5 | 1.6667 | MSA | Balance | <1 | 19.6 | 0.5 | 4.5 |
| | | 1 | | | | | |
| Example 6 | 0.5 | MSA | Balance | <1 | 54.5 | 9.1 | 0.9 |
| | | 1 | | | | | |
| Example 7 | 0.001 | MSA | Balance | <1 | 48 | 11.4 | 4.9 |
| | | 1 | | | | | |
| Example 8 | 0.05 | MSA | Balance | <1 | 27.2 | 6.4 | 0.2 |
| | | 1 | | | | | |

TABLE 2

| | (A) Oxidizing | (B) Fluoride ion | (C) First corrosion | |
|---|---|---|---|---|
| | agent | source compound | inhibitor | (D) Second corrosion |
| | [mass %] | [mass %] | [mass %] | inhibitor [mass %] |
| Example 9 | HIO₃ | HFSA | 5mBTA | N,N-Dimethyldodecylamine |
| | 0.0025 | 0.025 | 0.3 | (DMDDA) |
| | | | | 0.005 |
| Example 10 | HIO₃ | HFSA | 5mBTA | N,N-Dimethyldodecylamine |
| | 0.0025 | 0.025 | 0.3 | (DMDDA) |
| | | | | 0.01 |
| Example 11 | HIO₃ | HFSA | 5mBTA | N,N-Dimethyltetradecylamine |
| | 0.0025 | 0.025 | 0.3 | 0.0025 |
| Example 12 | HIO₃ | HFSA | 5mBTA | N,N-Dimethyltetradecylamine |
| | 0.0025 | 0.025 | 0.3 | 0.005 |
| Example 13 | HIO₃ | HFSA | 5mBTA | N,N-Dimethyltetradecylamine |
| | 0.0025 | 0.025 | 0.3 | 0.0075 |
| Example 14 | HIO₃ | HFSA | 5mBTA | N,N-Dimethyltetradecylamine |
| | 0.0025 | 0.025 | 0.3 | 0.01 |
| Example 15 | HIO₃ | HFSA | 5mBTA | N,N-Dimethylhexadecylamine |
| | 0.0025 | 0.025 | 0.3 | 0.0005 |
| Example 16 | HIO₃ | HFSA | 5mBTA | N,N-Dimethylhexadecylamine |
| | 0.0025 | 0.025 | 0.3 | 0.001 |
| Example 17 | HIO₃ | HFSA | 5mBTA | N,N-Dimethylhexadecylamine |
| | 0.0025 | 0.025 | 0.3 | 0.0015 |

| | (D) Second | | | | | | |
|---|---|---|---|---|---|---|---|
| | corrosion | | | | | | |
| | inhibitor/(C) First | | | | | | |
| | corrosion inhibitor | pH Adjuster | | | TiN | Mo | W |
| | (mass ratio) | [mass %] | Water | pH | [Å/min] | [Å/min] | [Å/min] |
| Example 9 | 0.0167 | MSA | Balance | <1 | 46 | 12 | 1.8 |
| | | 1 | | | | | |
| Example 10 | 0.0333 | MSA | Balance | <1 | 48 | 11 | 1.8 |
| | | 1 | | | | | |
| Example 11 | 0.0083 | MSA | Balance | <1 | 40 | 9 | 1.6 |
| | | 1 | | | | | |
| Example 12 | 0.1667 | MSA | Balance | <1 | 25 | 7 | 1.2 |
| | | 1 | | | | | |
| Example 13 | 0.025 | MSA | Balance | <1 | 29 | 7 | 1.3 |
| | | 1 | | | | | |
| Example 14 | 0.0333 | MSA | Balance | <1 | 30 | 7 | 1.2 |
| | | 1 | | | | | |
| Example 15 | 0.0017 | MSA | Balance | <1 | 56 | 12 | 3.4 |
| | | 1 | | | | | |
| Example 16 | 0.0033 | MSA | Balance | <1 | 48 | 10 | 1.7 |
| | | 1 | | | | | |
| Example 17 | 0.005 | MSA | Balance | <1 | 51 | 8 | 0.7 |
| | | 1 | | | | | |

TABLE 3

| | (A) Oxidizing | (B) Fluoride ion | | (D) Second corrosion |
|---|---|---|---|---|
| | agent | source compound | (C) First corrosion | inhibitor |
| | [mass %] | [mass %] | inhibitor [mass %] | [mass %] |
| Example 18 | HIO₃ | HFSA | 5-Methyl-1H-benzimidazole | DMDDA |
| | 0.0025 | 0.025 | 0.3 | 0.015 |
| Example 19 | HIO₃ | HFSA | 2,6-Dimethylbenzothiazole | DMDDA |
| | 0.0025 | 0.025 | 0.3 | 0.015 |
| Example 20 | HIO₃ | HFSA | 1,2,3-Benzotriazole | DMDDA |
| | 0.0025 | 0.025 | 0.3 | 0.015 |
| Example 21 | HIO₃ | HFSA | 1H-1,2,3-Triazolo[4,5-b] | DMDDA |
| | 0.0025 | 0.025 | pyridine | 0.015 |
| | | | 0.3 | |
| Example 22 | HIO₃ | HFSA | Indazole | DMDDA |
| | 0.0025 | 0.025 | 0.3 | 0.015 |
| Example 23 | HIO₃ | HFSA | 3-Phenylpyrazole | DMDDA |
| | 0.0025 | 0.025 | 0.3 | 0.015 |
| Example 24 | HIO₃ | HFSA | 4-Fluoroindazole | DMDDA |
| | 0.0025 | 0.025 | 0.3 | 0.015 |
| Example 25 | HIO₃ | HFSA | 5-Nitroindazole | DMDDA |
| | 0.0025 | 0.025 | 0.3 | 0.015 |
| Example 26 | HIO₃ | HFSA | Indazole-3-carboxylic Acid | DMDDA |
| | 0.0025 | 0.025 | 0.3 | 0.015 |
| Example 27 | HIO₃ | HFSA | 5-Methyl-1H-indazole | DMDDA |
| | 0.0025 | 0.025 | 0.3 | 0.015 |

| | (D) Second | | | | | | |
|---|---|---|---|---|---|---|---|
| | corrosion | | | | | | |
| | inhibitor/(C) First | | | | | | |
| | corrosion | | | | | | |
| | inhibitor | pH Adjuster | | | TiN | Mo | W |
| | (mass ratio) | [mass %] | Water | pH | [Å/min] | [Å/min] | [Å/min] |
| Example 18 | 0.05 | MSA | Balance | <1 | 39 | 16 | 0 |
| | | 1 | | | | | |
| Example 19 | 0.05 | MSA | Balance | <1 | 55 | 17 | 1 |
| | | 1 | | | | | |
| Example 20 | 0.05 | MSA | Balance | <1 | 54 | 16 | 1 |
| | | 1 | | | | | |
| Example 21 | 0.05 | MSA | Balance | <1 | 48 | 16 | 1 |
| | | 1 | | | | | |
| Example 22 | 0.05 | MSA | Balance | <1 | 45 | 8 | 2 |
| | | 1 | | | | | |
| Example 23 | 0.05 | MSA | Balance | <1 | 45 | 11 | 1 |
| | | 1 | | | | | |
| Example 24 | 0.05 | MSA | 99 | <1 | 41 | 5 | 1 |
| | | 1 | | | | | |
| Example 25 | 0.05 | MSA | 99 | <1 | 54 | 11 | 0 |
| | | 1 | | | | | |
| Example 26 | 0.05 | MSA | 99 | <1 | 41 | 15 | 1 |
| | | 1 | | | | | |
| Example 27 | 0.05 | MSA | 99 | <1 | 41 | 5 | 1 |
| | | 1 | | | | | |

TABLE 4

| | (A) Oxidizing | (B) Fluoride ion | (C) First | (D) Second |
|---|---|---|---|---|
| | agent | source compound | corrosion | corrosion inhibitor |
| | [mass %] | [mass %] | inhibitor [mass %] | [mass %] |
| Example 28 | HIO₃ | HFSA | 4-Fluoroindazole | DMDDA |
| | 0.0025 | 0.025 | 0.03 | 0.015 |
| Comparative | HIO₃ | HFSA | 4-Fluoroindazole | DMDDA |
| Example 4 | 0.0025 | 0.025 | 0.003 | 0.015 |
| Example 29 | HIO₃ | HFSA | 5-Nitroindazole | DMDDA |
| | 0.0025 | 0.025 | 0.03 | 0.015 |
| Comparative | HIO₃ | HFSA | 5-Nitroindazole | DMDDA |
| Example 5 | 0.0025 | 0.025 | 0.003 | 0.015 |
| Example 30 | HIO₃ | HFSA | Indazole-3- | DMDDA |
| | 0.0025 | 0.025 | carboxylic Acid | 0.015 |
| | | | 0.03 | |
| Comparative | HIO₃ | HFSA | Indazole-3 | DMDDA |
| Example 6 | 0.0025 | 0.025 | carboxylic Acid | 0.015 |
| | | | 0.003 | |
| Comparative | Ammonium | HFSA | None | None |
| Example 7 | persulfate | 0.025 | | |
| | 0.025 | | | |
| Example 31 | Ammonium | HFSA | 5mBTA | DMDDA |
| | persulfate | 0.025 | 0.3 | 0.015 |
| | 0.025 | | | |

| | (D) Second | | | | | | |
|---|---|---|---|---|---|---|---|
| | corrosion | | | | | | |
| | inhibitor/(C) | | | | | | |
| | First corrosion | | | | | | |
| | inhibitor | pH Adjuster | | | TiN | Mo | W |
| | (mass ratio) | [mass %] | Water | pH | [Å/min] | [Å/min] | [Å/min] |
| Example 28 | 0.5 | MSA | Balance | <1 | 53 | 10 | 0.6 |
| | | 1 | | | | | |
| Comparative | 5 | MSA | Balance | <1 | 49 | 27.3 | 0.8 |
| Example 4 | | 1 | | | | | |
| Example 29 | 0.5 | MSA | Balance | <1 | 50 | 12.1 | 0.7 |
| | | 1 | | | | | |
| Comparative | 5 | MSA | Balance | <1 | 54 | 37.9 | 0.7 |
| Example 5 | | 1 | | | | | |
| Example 30 | 0.5 | MSA | Balance | <1 | 50 | 20.6 | 0.5 |
| | | 1 | | | | | |
| Comparative | 5 | MSA | Balance | <1 | 45 | 55.5 | 0.7 |
| Example 6 | | 1 | | | | | |
| Comparative | — | MSA | Balance | <1 | 44 | 71 | 58.1 |
| Example 7 | | 1 | | | | | |
| Example 31 | 0.05 | MSA | Balance | <1 | 41 | 12 | 0.9 |
| | | 1 | | | | | |

TABLE 5

| | (A) Oxidizing | (B) Fluoride ion | (C) First | (D) Second |
|---|---|---|---|---|
| | agent | source compound | corrosion | corrosion |
| | [mass %] | [mass %] | inhibitor [mass %] | inhibitor [mass %] |
| Comparative | None | HFSA | 5mBTA | DMDDA |
| Example 8 | | 0.025 | 0.3 | 0.015 |
| Example 32 | HIO₃ | HFSA | 5mBTA | DMDDA |
| | 0.0001 | 0.025 | 0.3 | 0.015 |
| Example 33 | HIO₃ | HFSA | 5mBTA | DMDDA |
| | 0.0002 | 0.025 | 0.3 | 0.015 |
| Example 34 | HIO₃ | HFSA | 5mBTA | DMDDA |
| | 0.0003 | 0.025 | 0.3 | 0.015 |
| Example 35 | HIO₃ | HFSA | 5mBTA | DMDDA |
| | 0.0004 | 0.025 | 0.3 | 0.015 |
| Example 36 | HIO₃ | HFSA | 5mBTA | DMDDA |
| | 0.0005 | 0.025 | 0.3 | 0.015 |
| Example 37 | HIO₃ | HFSA | 5mBTA | DMDDA |
| | 0.001 | 0.025 | 0.3 | 0.015 |
| Example 38 | HIO₃ | HFSA | 5mBTA | DMDDA |
| | 0.0015 | 0.025 | 0.3 | 0.015 |
| Example 39 | HIO₃ | HFSA | 5mBTA | DMDDA |
| | 0.005 | 0.025 | 0.3 | 0.015 |
| Example 40 | HIO₃ | HFSA | 5mBTA | DMDDA |
| | 0.0075 | 0.025 | 0.3 | 0.015 |
| Example 41 | HIO₃ | HFSA | 5mBTA | DMDDA |
| | 0.01 | 0.025 | 0.3 | 0.015 |

| | (D) Second | | | | | | |
|---|---|---|---|---|---|---|---|
| | corrosion | | | | | | |
| | inhibitor/(C) | | | | | | |
| | First corrosion | | | | | | |
| | inhibitor | pH Adjuster | | | TiN | Mo | W |
| | (mass ratio) | [mass %] | Water | pH | [Å/min] | [Å/min] | [Å/min] |
| Comparative | 0.05 | MSA | Balance | <1 | 2 | 1.4 | 0.9 |
| Example 8 | | 1 | | | | | |
| Example 32 | 0.05 | MSA | Balance | <1 | 25 | 3.4 | 1.8 |
| | | 1 | | | | | |
| Example 33 | 0.05 | MSA | Balance | <1 | 34 | 4.2 | 2.3 |
| | | 1 | | | | | |
| Example 34 | 0.05 | MSA | Balance | <1 | 44 | 7 | 2.5 |
| | | 1 | | | | | |
| Example 35 | 0.05 | MSA | Balance | <1 | 48 | 9 | 2.7 |
| | | 1 | | | | | |
| Example 36 | 0.05 | MSA | Balance | <1 | 49 | 9.7 | 2.4 |
| | | 1 | | | | | |
| Example 37 | 0.05 | MSA | Balance | <1 | 55 | 9.5 | 1.5 |
| | | 1 | | | | | |
| Example 38 | 0.05 | MSA | Balance | <1 | 53 | 9 | 1.2 |
| | | 1 | | | | | |
| Example 39 | 0.05 | MSA | Balance | <1 | 45 | 8.9 | 1.1 |
| | | 1 | | | | | |
| Example 40 | 0.05 | MSA | Balance | <1 | 43 | 9.2 | 0.8 |
| | | 1 | | | | | |
| Example 41 | 0.05 | MSA | Balance | <1 | 36 | 9.2 | 1.4 |
| | | 1 | | | | | |

TABLE 6

| | (A) Oxidizing | (B) Fluoride ion | (C) First | (D) Second |
|---|---|---|---|---|
| | agent | source compound | corrosion | corrosion |
| | [mass %] | [mass %] | inhibitor [mass %] | inhibitor [mass %] |
| Example 42 | Ammonium | HFSA | 5mBTA | DMDDA |
| | persulfate | 0.025 | 0.03 | 0.015 |
| | 0.00025 | | | |
| Comparative | Ammonium | HFSA | 5mBTA | DMDDA |
| Example 9 | persulfate | 0.025 | 0.003 | 0.015 |
| | 0.0025 | | | |
| Example 43 | Ammonium | HFSA | 5mBTA | DMDDA |
| | persulfate | 0.025 | 0.03 | 0.015 |
| | 0.025 | | | |
| Comparative | Ammonium | HFSA | 5mBTA | DMDDA |
| Example 10 | persulfate | 0.025 | 0.003 | 0.015 |
| | 0.25 | | | |
| Example 44 | Ammonium | HFSA | 5mBTA | DMDDA |
| | persulfate | 0.025 | 0.03 | 0.015 |
| | 2.5 | | | |
| Comparative | HIO₃ | HF | None | None |
| Example 11 | 0.0025 | 0.02 | | |
| Example 45 | HIO₃ | HF | 5mBTA | DMDDA |
| | 0.0025 | 0.02 | 0.3 | 0.015 |

| | (D) Second | | | | | | |
|---|---|---|---|---|---|---|---|
| | corrosion | | | | | | |
| | inhibitor/(C) | | | | | | |
| | First corrosion | | | | | | |
| | inhibitor | pH Adjuster | | | TiN | Mo | W |
| | (mass ratio) | [mass %] | Water | pH | [Å/min] | [Å/min] | [Å/min] |
| Example 42 | 0.5 | MSA | Balance | <1 | 20 | 10 | 1 |
| | | 1 | | | | | |
| Comparative | 5 | MSA | Balance | <1 | 39 | 70 | 1.2 |
| Example 9 | | 1 | | | | | |
| Example 43 | 0.5 | MSA | Balance | <1 | 44 | 14 | 1.3 |
| | | 1 | | | | | |
| Comparative | 5 | MSA | Balance | <1 | 53 | 76 | 1.7 |
| Example 10 | | 1 | | | | | |
| Example 44 | 0.5 | MSA | Balance | <1 | 54 | 15 | 1.4 |
| | | 1 | | | | | |
| Comparative | — | MSA | Balance | 2.7 | 47 | 65 | 53.6 |
| Example 11 | | 1 | | | | | |
| Example 45 | 0.05 | MSA | Balance | 2.7 | 47 | 12 | 0.8 |
| | | 1 | | | | | |

TABLE 7

| | (A) Oxidizing | (B) Fluoride ion | (C) First | (D) Second |
|---|---|---|---|---|
| | agent | source compound | corrosion | corrosion |
| | [mass %] | [mass %] | inhibitor [mass %] | inhibitor [mass %] |
| Comparative | HIO₃ | HF | 5mBTA | DMDDA |
| Example 12 | 0.0025 | 0.00025 | 0.3 | 0.015 |
| Comparative | HIO₃ | HF | 5mBTA | DMDDA |
| Example 13 | 0.0025 | 0.0025 | 0.3 | 0.015 |
| Example 46 | HIO₃ | HF | 5mBTA | DMDDA |
| | 0.0025 | 0.005 | 0.3 | 0.015 |
| Example 47 | HIO₃ | HF | 5mBTA | DMDDA |
| | 0.0025 | 0.01 | 0.3 | 0.015 |
| Example 48 | HIO₃ | HF | 5mBTA | DMDDA |
| | 0.0025 | 0.015 | 0.3 | 0.015 |
| Example 49 | HIO₃ | HF | 5mBTA | DMDDA |
| | 0.0025 | 0.02 | 0.3 | 0.015 |
| Example 50 | HIO₃ | HF | 5mBTA | DMDDA |
| | 0.0025 | 0.025 | 0.3 | 0.015 |
| Example 51 | HIO₃ | HF | 5mBTA | DMDDA |
| | 0.0025 | 0.05 | 0.3 | 0.015 |
| Example 52 | HIO₃ | HF | 5mBTA | DMDDA |
| | 0.0025 | 0.1 | 0.3 | 0.015 |
| Example 53 | HIO₃ | HFSA | 5mBTA | DMDDA |
| | 0.0025 | 0.025 | 0.3 | 0.015 |
| Example 54 | HIO₃ | HFSA | 5mBTA | DMDDA |
| | 0.0025 | 0.025 | 0.3 | 0.015 |
| Example 55 | HIO₃ | HFSA | 5mBTA | DMDDA |
| | 0.0025 | 0.025 | 0.3 | 0.015 |

| | (D) Second | | | | | | |
|---|---|---|---|---|---|---|---|
| | corrosion | | | | | | |
| | inhibitor/(C) | | | | | | |
| | First corrosion | | | | | | |
| | inhibitor | pH Adjuster | | | TiN | Mo | W |
| | (mass ratio) | [mass %] | Water | pH | [Å/min] | [Å/min] | [Å/min] |
| Comparative | 0.05 | MSA | Balance | <1 | −1 | 12.1 | 0.8 |
| Example 12 | | 1 | | | | | |
| Comparative | 0.05 | MSA | Balance | <1 | 2 | 9.6 | 0.6 |
| Example 13 | | 1 | | | | | |
| Example 46 | 0.05 | MSA | Balance | <1 | 17 | 9.7 | 0.8 |
| | | 1 | | | | | |
| Example 47 | 0.05 | MSA | Balance | <1 | 24 | 12.1 | 1.1 |
| | | 1 | | | | | |
| Example 48 | 0.05 | MSA | Balance | <1 | 38 | 12.2 | 1.3 |
| | | 1 | | | | | |
| Example 49 | 0.05 | MSA | Balance | <1 | 47 | 12.1 | 0.8 |
| | | 1 | | | | | |
| Example 50 | 0.05 | MSA | Balance | <1 | 69 | 11.6 | 1.1 |
| | | 1 | | | | | |
| Example 51 | 0.05 | MSA | Balance | <1 | 98 | 11.4 | 0.5 |
| | | 1 | | | | | |
| Example 52 | 0.05 | MSA | Balance | <1 | 110 | 11.5 | 0.9 |
| | | 1 | | | | | |
| Example 53 | 0.05 | Benzene | Balance | <1 | 41 | 10 | 1 |
| | | sulfonic acid | | | | | |
| | | 1 | | | | | |
| Example 54 | 0.05 | HCl | Balance | <1 | 43 | 11 | 1 |
| | | 1 | | | | | |
| Example 55 | 0.05 | HBr | Balance | <1 | 34 | 11 | 1 |
| | | 1 | | | | | |

From the above, at least it has been found that the processing solution of each of the present Examples is excellent in ability to remove a titanium atom-containing layer and titanium-based residues and is excellent in anticorrosion properties for a tungsten atom-containing layer and a molybdenum atom-containing layer.

### REFERENCE SIGNS LIST

100 semiconductor substrate
10 substrate
12 metal wiring layer
14 low-k film
16 hard mask layer
P residue

What is claimed is:

1. A processing solution comprising:
(A) an oxidizing agent;
(B) a compound capable of releasing a fluoride ion;
(C) at least one selected from the group consisting of a nitrogen atom-containing heterocyclic ring-containing compound and a salt thereof as a first corrosion inhibitor;
(D) at least one selected from the group consisting of an amine compound (1) having a structure represented by Formula (1) and a salt thereof as a second corrosion inhibitor; and
water,
wherein a content amount of (B) the compound capable of releasing a fluoride ion is 0.005 to 1 mass %, and
a content amount of (C) the first corrosion inhibitor is 0.01 to 1 mass %,
NR¹R²R³ (1)
(wherein R¹, R², and R³ each independently represent a hydrogen atom, an alkyl group, or an alkyl group having an organic group, provided that at least one of R¹, R², and R³ represents an alkyl group having 8 or more carbon atoms or an alkyl group having 8 or more carbon atoms and having an organic group).

2. The processing solution according to claim 1, wherein
(C) the first corrosion inhibitor is at least one selected from the group consisting of a benzotriazole ring-containing compound, a triazole ring-containing compound, a benzimidazole ring-containing compound, an imidazole ring-containing compound, an indazole ring-containing compound, a pyrazole ring-containing compound, a benzothiazole ring-containing compound, and salts thereof.

3. The processing solution according to claim 1, wherein
(C) the first corrosion inhibitor is at least one selected from the group consisting of 5-methyl-1H-benzotriazole, 5-methyl-1H-benzimidazole, 2,6-dimethylbenzothiazole, 1,2,3-benzotriazole, 1H-1,2,3-triazolo[4,5-b]pyridine, indazole, 3-phenylpyrazole, 1,2,4-triazole, 2-propylimidazole, 4-fluoroindazole, 5-nitroindazole, indazole-3-carboxylic acid, 5-methyl-1H-indazole, and salts thereof.

4. The processing solution according to claim 1, wherein
(D) the second corrosion inhibitor is at least one selected from the group consisting of n-octylamine, 1-aminodecane, dodecylamine, hexadecylamine, N,N-dimethyldodecylamine, N,N-dimethyltetradecylamine, and N,N-dimethylhexadecylamine.

5. The processing solution according to claim 1, wherein
a content amount of (A) the oxidizing agent is 0.0001 to 3 mass %.

6. The processing solution according to claim 1, wherein
a content amount of (D) the second corrosion inhibitor is 0.0001 to 10 mass %.

7. The processing solution according to claim 1, wherein
a mass ratio (D/C) of a content amount of (D) the second corrosion inhibitor to a content amount of (C) the first corrosion inhibitor is 0.001 to 10.

8. The processing solution according to claim 1,
used for processing of a semiconductor substrate comprising a substrate, a layer containing tungsten atoms and/or a layer containing molybdenum atoms, and a layer containing titanium atoms.

9. A method for processing a semiconductor substrate, the method comprising a step of using the processing solution according to claim 1 to process a semiconductor substrate comprising a substrate, a layer containing tungsten atoms and/or a layer containing molybdenum atoms, and a layer containing titanium atoms.

10. A method for manufacturing a semiconductor device, the method comprising a step of using the processing solution according to claim 1 to process a semiconductor substrate comprising a substrate, a layer containing tungsten atoms and/or a layer containing molybdenum atoms, and a layer containing titanium atoms.
